(19) United States
(12) Patent Application Publication
(10) Pub. No.: US 2024/0145564 A1
(43) Pub. Date: May 2, 2024

(54) Semiconductor structure and the forming method thereof

(71) Applicant: UNITED MICROELECTRONICS CORP., Hsin-Chu City (TW)

(72) Inventors: Tzu-I Tsai, Tainan City (TW); Shih-An Huang, Tainan City (TW)

(73) Assignee: UNITED MICROELECTRONICS CORP., Hsin-Chu City (TW)

(21) Appl. No.: 17/994,007

(22) Filed: Nov. 25, 2022

(30) Foreign Application Priority Data
Nov. 2, 2022 (CN) 202211361555.X

(51) Int. Cl. H01L 29/423; H01L 29/40

(52) U.S. Cl. CPC H01L 29/42364; H01L 29/401

(57) ABSTRACT

The invention provides a semiconductor structure, which comprises a substrate, a gate dielectric layer on the substrate, wherein the gate dielectric layer comprises two sidewall portions and a horizontal portion between the two sidewall portions, wherein a height of the horizontal portion is lower than that of the two sidewall portions, and the horizontal portion and the two sidewall portions are perpendicular to each other, and a gate conductive layer on the horizontal portion of the gate dielectric layer.

### BACKGROUND OF THE INVENTION

### 1. Field of the Invention

The invention relates to the semiconductor field, in particular to the structure and manufacturing method of high voltage metal oxide field effect (HV-MOS) with oxide layers with different thicknesses.

### 2. Description of the Prior Art

Metal oxide field effect transistor (MOSFET) is widely used in various circuit structures, in which the metal oxide field effect transistor used as the working structure of high voltage circuit is also called high voltage metal oxide field effect transistor (HV-MOSFET).

In the manufacture of high-voltage integrated circuits, high-voltage MOSFET arrays are often used to provide large output current. As HV-MOS introduces high voltage, it will generate strong electric field, especially the maximum electric field near the edge of the gate, which may cause the electric field to pass through the gate and damage the components.

Therefore, an improved HV-MOS structure is needed, which can reduce the probability of the above problems.

### SUMMARY OF THE INVENTION

The invention provides a semiconductor structure, which comprises a substrate, a gate dielectric layer on the substrate, wherein the gate dielectric layer comprises two sidewall portions and a horizontal portion between the two sidewall portions, wherein a height of the horizontal portion is lower than that of the two sidewall portions, and the horizontal portion and the two sidewall portions are perpendicular to each other, and a gate conductive layer on the horizontal portion of the gate dielectric layer.

The invention further provides a method for forming a semiconductor structure includes forming a substrate, forming a gate dielectric layer on the substrate, wherein the gate dielectric layer includes two sidewall portions and a horizontal portion between the two sidewall portions, wherein a height of the horizontal portion is lower than that of the two sidewall portions, and the horizontal portion and the two sidewall portions are perpendicular to each other, and forming a gate conductive layer on the horizontal portion of the gate dielectric layer.

The present invention is characterized in that, when the gate mandrel structure (such as monocrystalline silicon) is removed, a part of the gate dielectric layer is additionally etched, so that the gate dielectric layer sinks, and a gate dielectric layer with a similar U shape is formed. In this way, the following two advantages can be achieved: one is to reduce the gate dielectric layer in the central part, which can further increase the turn-on current (Ion); the other advantage is that the gate dielectric layer has a vertical wall-like structure at both ends, and the thicker thickness can avoid problems such as tunneling and leakage current caused by over-strong electric field at both ends of the gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 5 are schematic cross-sectional views of the process of fabricating a high voltage metal oxide field effect transistor (HV-MOS) according to the first preferred embodiment of the present invention.

FIGS. 6 to 7 are schematic cross-sectional views of the process of fabricating a high voltage metal oxide field effect transistor (HV-MOS) according to the second preferred embodiment of the present invention.

FIGS. 8-9 are schematic cross-sectional views of the process of fabricating a high voltage metal oxide field effect transistor (HV-MOS) according to the third preferred embodiment of the present invention.

FIG. 10 is a schematic cross-sectional view of a high voltage metal oxide field effect transistor (HV-MOS) according to the fourth preferred embodiment of the present invention.

FIG. 11 shows a top view of the arrangement of the gate and other adjacent dummy gates of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

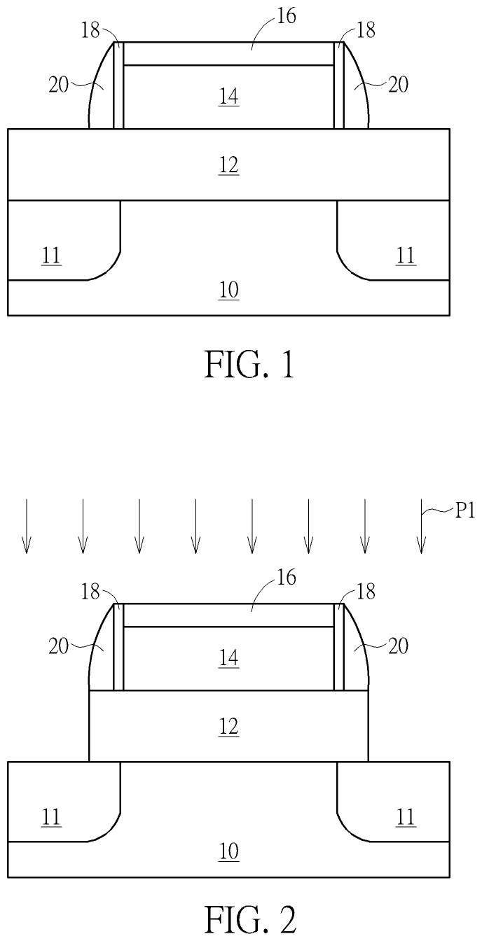

FIGS. 1 to 5 are schematic cross-sectional views of the process of fabricating a high voltage metal oxide field effect transistor (HV-MOS) according to the first preferred embodiment of the present invention. As shown in FIG. 1, firstly, a substrate 10, such as a silicon substrate, is provided. A plurality of fin structures (not shown) are formed on the substrate 10, and a drift region 11 is formed in the substrate 10, for example, by doping ions. Then, a gate dielectric layer 12 is formed on the substrate 10, a dummy mandrel structure 14 and a mask layer 16 are additionally formed on the gate dielectric layer 12. Afterwards, a first spacer 18 and a second spacer 20 are respectively formed on both sides of the dummy mandrel structure 14 and the mask layer 16. In this embodiment, the gate dielectric layer 12 is made of silicon oxide, the dummy mandrel structure 14 is made of monocrystalline silicon or polycrystalline silicon, and the mask layer 16, the first spacer 18 and the second spacer 20 are made of insulating materials such as silicon oxide, silicon nitride and silicon oxynitride. The materials of the above elements can be adjusted according to actual requirements, and the present invention is not limited to this. In addition, the manufacturing methods of the above-mentioned elements belong to the conventional technology in the field, and will not be described in detail here.

In addition, in this embodiment, since the gate dielectric layer 12 is formed before the first spacer 18 and the second spacer 20 are formed, the bottom surfaces of the first spacer 18 and the second spacer 20 are aligned with the top surface of the gate dielectric layer 12. In addition, in this embodiment, the first spacer 18 has a vertical structure, while the second spacer 20 has a sail-like structure (the bottom is wider and the upper part is narrower). In other embodiments of the present invention, it is also possible to form only a single-layer spacer instead of the double-layer spacer in this embodiment, and this embodiment is also within the scope of the present invention.

Then, as shown in FIG. 2, an etching step P1 is performed to remove part of the gate dielectric layer 12 not covered by the mask layer 16, the first spacer 18 and the second spacer 20, so as to expose a part of the drift region 11. The purpose of removing part of the gate dielectric layer 12 here is to expose the drift region 11, so as to facilitate the ion doping of the source/drain regions.

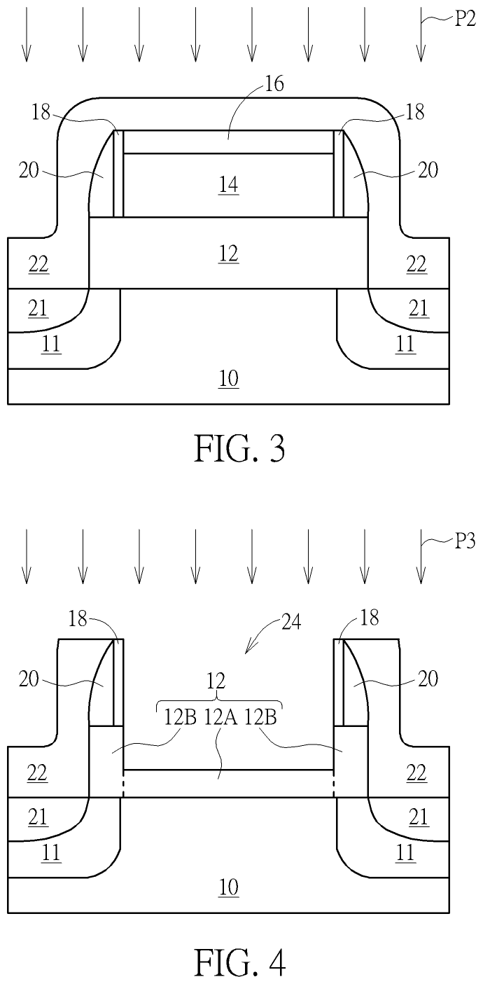

Then, as shown in FIG. 3, ion doping step P2 is performed to form source/drain regions 21 in the drift region 11, and then a contact etch stop layer (CESL) 22 is formed to cover the substrate 10, the source/drain regions 22, the second spacer 20, the first spacer 18 and the mask layer 16. Both the source/drain region 22 and the drift region 11 are doped with ions. The difference between them is that the concentration of ion doping in the source/drain region 22 is higher. The type of doped ions can be adjusted according to actual requirements, and the invention is not limited to this. The material of the contact stop layer 22 is, for example, an insulating material such as silicon oxide, silicon nitride, silicon oxynitride, etc., but the present invention is not limited to this.

As shown in FIG. 4, a planarization step or an etching step (not shown) is performed to remove the contact etching stop layer 22 on the top surface of the mask layer 16 to expose the mask layer 16, and then an etching step P3 is performed to remove the mask layer 16, the dummy mandrel structure 14 and a part of the gate dielectric layer 12, and a recess 24 is formed, wherein the bottom surface of the recess 24 is lower than the top surface of the original gate dielectric layer 12. The etching step P3 may include multiple etching steps to remove different material layers (the mask layer 16, the dummy mandrel structure 14 and a part of the gate dielectric layer 12). In addition, it is worth noting that compared with the prior art, the etching step in the prior art usually only removes the mask layer 16 and the dummy mandrel structure 14, but does not remove part of the gate dielectric layer 12. In this embodiment, an extra part of the gate dielectric layer 12 is removed, so that the top surface of the gate dielectric layer 12 is lowered. After the etching step P3 is completed, the remaining gate dielectric layer 12 has a structure with a lower central portion and higher sidewall portions. Here, it can be further defined that the lower central portion of the gate dielectric layer 12 is a horizontal portion 12A, and the higher sidewall portion are sidewall portions 12B, the thickness of the horizontal portion 12A is smaller than the thickness of the sidewall portion 12B, but the horizontal portion 12A is aligned with the bottom surface of the sidewall portion 12B, and the horizontal portion 12A is basically perpendicular to the sidewall portion 12B (for example, along the horizontal and vertical directions respectively.

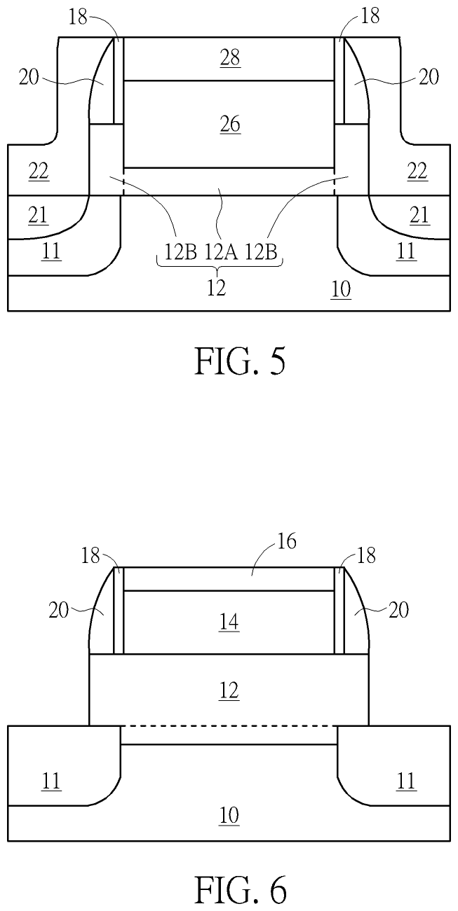

Then, as shown in FIG. 5, a metal gate replacement process (RMG) is continued to form the gate, that is, a gate conductive layer 26 and a mask layer 28 are filled in the groove above the gate dielectric layer 12, wherein the gate conductive layer 26 is made of metal or metal oxide with excellent filling ability and low resistance, such as tungsten (W), aluminum (Al), titanium aluminum (TiAl) or titanium aluminum oxide (TiAlO), and the mask layer 28 is made of insulating materials such as silicon oxide, silicon nitride, silicon oxynitride, etc., but the present invention is not limited to this. In addition, between the gate conductive layer 28 and the gate dielectric layer 12, a high dielectric constant layer (not shown) may be included, and the material is HfOx, TiNx, TaNx, TiAlCx (where x is an integer), etc. The process of forming the gate conductive layer 26 and the mask layer 28 here belongs to the conventional technology in the field, and will not be described in detail here.

As shown in FIGS. 1-5 above, in this embodiment, part of the gate dielectric layer 12 is additionally removed by the etching step P3, so that the gate dielectric layer has a structure with a lower central portion and higher two sidewall portions, which is similar to a wider U-shaped structure. The gate dielectric layer 12 with this shape has several advantages. Firstly, the turn-on current (Ion) of the gate dielectric layer is inversely proportional to the thickness of the gate dielectric layer, so reducing the thickness of the horizontal portion 12A of the gate dielectric layer 12 can further increase the turn-on current (Ion) of HV-MOS. Another advantage is that thick sidewall portions 12B are reserved at both ends of the gate dielectric layer 12, which can avoid problems such as tunneling, leakage current, etc. caused by excessive electric field at the corners of both ends of the gate of HV-MOS. Therefore, the quality and yield of HV-MOS can be improved under the condition of compatibility with existing processes. In addition, the ratio of the height of the horizontal portion 12A and the sidewall portion 12B of the gate dielectric layer 12 can be adjusted according to the actual requirements, and it is preferably between 0.7 and 0.95 in this embodiment, but it is not limited to this.

Hereinafter, different embodiments of the semiconductor structure and the manufacturing method of the present invention will be described, and to simplify the description, the following description mainly focuses on the differences of each embodiment, instead of repeating the similarities. In addition, the same elements in each embodiment of the present invention are labeled with the same reference numerals, so as to facilitate the cross-reference among the embodiments.

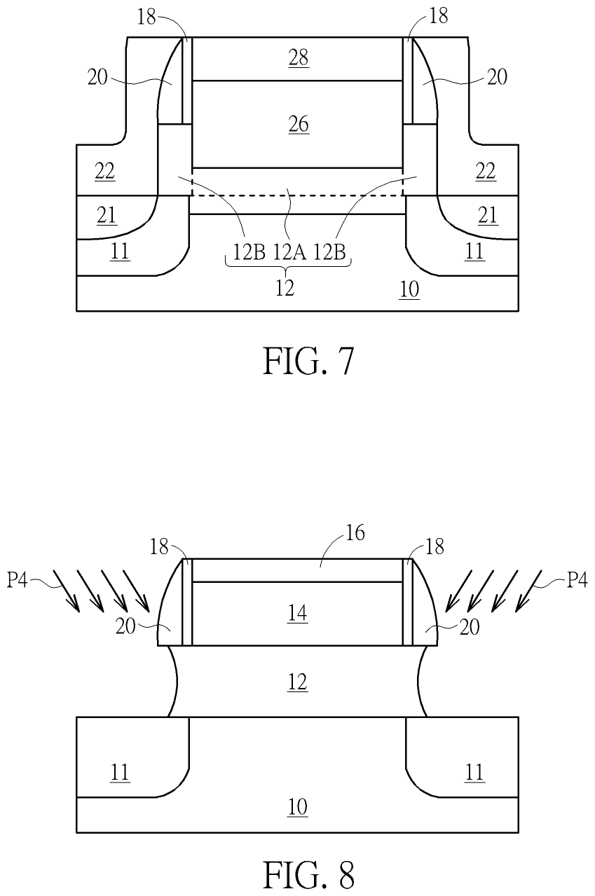

FIGS. 6 to 7 are schematic cross-sectional views of the process of fabricating a high voltage metal oxide field effect transistor (HV-MOS) according to the second preferred embodiment of the present invention. In this embodiment, most elements and steps are the same as those described in the first embodiment, and these elements are denoted by the same reference numerals, and their manufacturing methods are not repeated. The difference between this embodiment and the first embodiment is that when the gate dielectric layer 12 is formed, a part of the substrate 10 is removed by an etching step to form a recess in the substrate 10, and then the gate dielectric layer 12 is formed to fill the recess. Therefore, in this embodiment, a part of the gate dielectric layer 12 penetrates into the substrate 10, that is, a bottom surface of the gate dielectric layer 12 is lower than the top surface of the substrate 10.

After the subsequent process is continued with the structure shown in FIG. 6 (the process is the same as that shown in FIGS. 2-5 of the first embodiment, so the details will not be repeated here), as shown in FIG. 7, an HV-MOS structure is formed. In this embodiment, the horizontal portion 12A of the gate dielectric layer 12 penetrates into a part of the substrate 10. Compared with the first embodiment, the bottom surface of the gate dielectric layer 12 is lower than the upper surface of the substrate 10, that is, farther away from the part with the strongest electric field. Therefore, compared with the first embodiment, the structure of this embodiment can further reduce the OFF current (Ioff) of HV-MOS and improve the quality of HV-MOS.

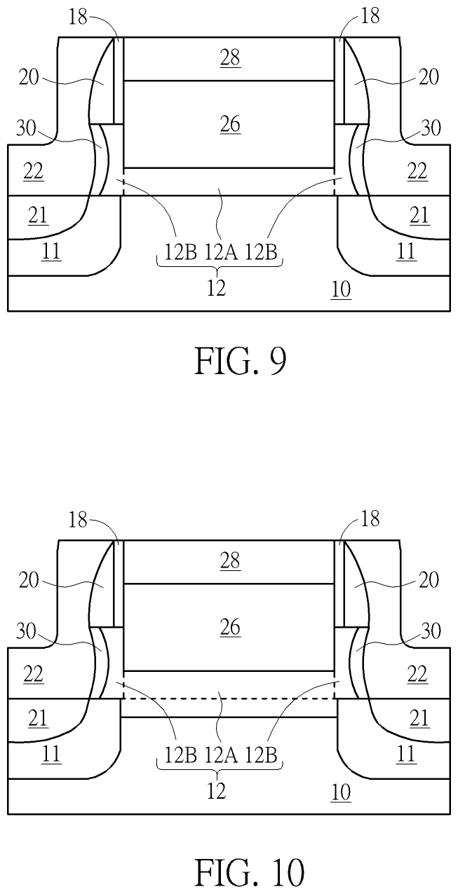

FIGS. 8-9 are schematic cross-sectional views of the process of fabricating a high voltage metal oxide field effect transistor (HV-MOS) according to the third preferred embodiment of the present invention. In this embodiment, most elements and steps are the same as those described in the first embodiment, and these elements are denoted by the same reference numerals, and their manufacturing methods are not repeated. The difference between this embodiment and the first embodiment is that, as shown in FIG. 8, after the gate dielectric layer 12 above the drift region 11 is removed (corresponding to the structure shown in FIG. 2 of the first embodiment), an additional etching step P4 (for example, wet etching) is performed to further etch the gate dielectric layer 12 laterally, so that the sidewalls of both ends of the gate dielectric layer 12 are recessed. Then, the same steps as the above-mentioned first embodiment are continued (the process is the same as that of FIGS. 3-5 of the first embodiment, so the details are omitted here). As shown in FIG. 9, the HV-MOS structure of this embodiment is roughly similar to that of FIG. 5 of the first embodiment, but the difference is that the air gap (void) 30 is located between the sidewall portion 12B, the second spacer 20 and the contact etch stop layer 22. In this embodiment, the air gap 30 is arranged beside the side wall 12B, which can further isolate the electric field and reduce the leakage current.

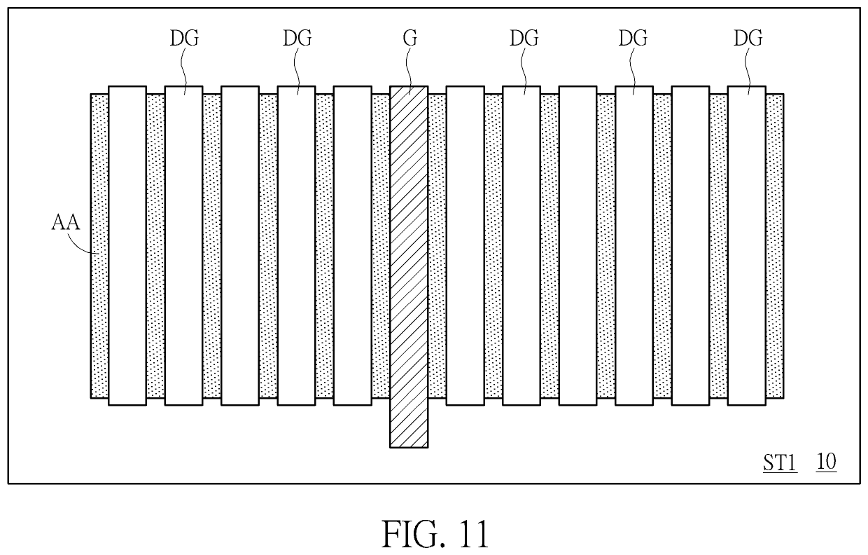

FIG. 10 is a schematic cross-sectional view of a high voltage metal oxide field effect transistor (HV-MOS) according to the fourth preferred embodiment of the present invention. As shown in FIG. 10, the structure of this embodiment integrates the advantages of the second preferred embodiment (corresponding to FIG. 7) and the third preferred embodiment (corresponding to FIG. 9), that is, the horizontal portion 12A extends into part of the substrate 10, and an air gap 30 is formed beside the sidewall portion 12B. The structure of this embodiment has the advantages of the above two embodiments, and this structure also belongs to the scope of the present invention.

FIG. 11 shows a top view of the arrangement of the gate of the present invention and other adjacent dummy gates. As mentioned above, the gate dielectric layer 12 and the gate conductive layer 26 are combined to form the gate G in the semiconductor device. In some embodiments, in order to improve the process yield of the semiconductor structure, other dummy gates DG will be formed beside the gate G when the gate G is formed, in which the dummy gate G is formed to improve the uniformity of the whole pattern, and prevent the density difference during pattern formation from affecting the process yield. In fact, the dummy gate DG is not connected to other electronic devices. In this embodiment, both the gate G and the dummy gate DG are located on the substrate 10, and the substrate 10 defines an active area AA and the surrounding shallow trench isolation STI. It is also worth noting that the length of the gate G in this embodiment may be longer than the length of other dummy gates DG, and a part of the gate G extends beyond the active area AA to the shallow trench isolation STI, and the excess can be used as the position where the subsequent contact structure (not shown) connects the gate G. In this embodiment, it is described that the gate G of the present invention can be formed together with the surrounding dummy gate DG to improve the process yield. However, the present invention is not limited to forming the dummy gate DG, and in some embodiments, only the gate G can be formed without forming the dummy gate DG.

According to the above description and drawings, the present invention provides a semiconductor structure, which comprises a substrate 10, a gate dielectric layer 12 on the substrate 10, wherein the gate dielectric layer 12 comprises two sidewall portions 12B and a horizontal portion 12A between the two sidewall portions 12B, wherein the height of the horizontal portion 12A is lower than that of the two sidewall portions 12B, and the horizontal portion 12A and the two sidewall portions 12B are perpendicular to each other, and a gate conductive layer 26 on the gate dielectric.

The present invention also provides a method for forming a semiconductor structure, which comprises forming a substrate 10, forming a gate dielectric layer 12 on the substrate 10, wherein the gate dielectric layer 12 comprises two sidewall portions 12B and a horizontal portion 12A between the two sidewall portions 12B, wherein the height of the horizontal portion 12A is lower than that of the two sidewall portions 12B, and the horizontal portion 12A is perpendicular to the two sidewall portions 12B, and forming a gate conductive layer 26 on the gate dielectric.

In some embodiments of the present invention, each sidewall 12B further comprises a first spacer 18 and a second spacer 20.

In some embodiments of the present invention, a bottom surface of the first spacer 18 and a bottom surface of the second spacer 20 are aligned with a top surface of the sidewall 12B.

In some embodiments of the present invention, a contact etch stop layer 22 is further included to cover the second spacer 20 and the substrate 10.

In some embodiments of the present invention, there is an air gap (void) 30 located beside the sidewall portion 12B, and the air gap 30 is located between the sidewall portion 12B, the second spacer 20 and the contact etch stop layer 22.

In some embodiments of the present invention, a bottom surface of the horizontal portion 12A is aligned with a bottom surface of the two sidewall portions 12B.

In some embodiments of the present invention, a bottom surface of the horizontal portion 12A is aligned with a top surface of the substrate 10.

In some embodiments of the present invention, a bottom surface of the horizontal portion 12A is lower than a top surface of the substrate 10.

In some embodiments of the present invention, the ratio of the height of the horizontal portion 12A to the height of the sidewall portion 12B is between 0.7 and 0.95.

In some embodiments of the present invention, the gate conductive layer 26 and the gate dielectric layer 12 are combined into a gate G, and a plurality of dummy gates DG are located beside the gate G, wherein a length of the gate G is longer than that of the dummy gates DG.

The present invention is characterized in that, when the gate mandrel structure (such as monocrystalline silicon) is removed, a part of the gate dielectric layer is additionally etched, so that the gate dielectric layer sinks, and a gate dielectric layer with a similar U shape is formed. In this way, the following two advantages can be achieved: one is to reduce the gate dielectric layer in the central part, which can further increase the turn-on current (Ion); the other advantage is that the gate dielectric layer has a vertical wall-like structure at both ends, and the thicker thickness can avoid problems such as tunneling and leakage current caused by over-strong electric field at both ends of the gate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure comprising:
a substrate;
a gate dielectric layer on the substrate, wherein the gate dielectric layer comprises two sidewall portions and a horizontal portion, and the horizontal portion is located between the two sidewall portions, wherein the height of the horizontal portion is lower than the height of the two sidewall portions, and the horizontal portion and the two sidewall portions are perpendicular to each other; and
a gate conductive layer located on the horizontal portion of the gate dielectric layer.

2. The semiconductor structure according to claim 1, further comprising a first spacer and a second spacer disposed on each sidewall portion.

3. The semiconductor structure according to claim 2, wherein a bottom surface of the first spacer and a bottom surface of the second spacer are aligned with a top surface of the sidewall portion.

4. The semiconductor structure according to claim 3, further comprising a contact etching stop layer covering the second spacer and the substrate.

5. The semiconductor structure according to claim 4, further comprising an air gap located beside the sidewall portion, and the air gap is located between the sidewall portion, the second spacer and the contact etch stop layer.

6. The semiconductor structure according to claim 1, wherein a bottom surface of the horizontal portion is aligned with a bottom surface of the two sidewall portions.

7. The semiconductor structure according to claim 1, wherein a bottom surface of the horizontal portion is aligned with a top surface of the substrate.

8. The semiconductor structure according to claim 1, wherein a bottom surface of the horizontal portion is lower than a top surface of the substrate.

9. The semiconductor structure according to claim 1, wherein the ratio of a height of the horizontal portion to a height of the sidewall portion is between 0.7 and 0.95.

10. The semiconductor structure according to claim 1, wherein the gate conductive layer and the gate dielectric layer are combined into a gate, and a plurality of dummy gates are located beside the gate, wherein a length of the gate is longer than a length of the dummy gate.

11. A method of forming a semiconductor structure, comprising:
forming a substrate;
forming a gate dielectric layer on the substrate, wherein the gate dielectric layer comprises two sidewall portions and a horizontal portion between the two sidewall portions, wherein a height of the horizontal portion is lower than a height of the two sidewall portions, and the horizontal portion and the two sidewall portions are perpendicular to each other; and
forming a gate conductive layer on the horizontal portion of the gate dielectric layer.

12. The method for forming a semiconductor structure according to claim 11, further comprising forming a first spacer and a second spacer on each sidewall portion.

13. The method for forming a semiconductor structure according to claim 12, wherein a bottom surface of the first spacer and a bottom surface of the second spacer are aligned with a top surface of the sidewall portion.

14. The method for forming a semiconductor structure according to claim 13, further comprising forming a contact etch stop layer to cover the second spacer and the substrate.

15. The method for forming a semiconductor structure according to claim 14, further comprising forming an air gap beside the sidewall portion, and the air gap is located between the sidewall portion, the second spacer and the contact etch stop layer.

16. The method for forming a semiconductor structure according to claim 11, wherein a bottom surface of the horizontal portion is aligned with a bottom surface of the two sidewall portions.

17. The method for forming a semiconductor structure according to claim 11, wherein a bottom surface of the horizontal portion is aligned with a top surface of the substrate.

18. The method for forming a semiconductor structure according to claim 11, wherein a bottom surface of the horizontal portion is lower than a top surface of the substrate.

19. The method for forming a semiconductor structure according to claim 11, wherein the ratio of the height of the horizontal portion to the height of the sidewall portion is between 0.7 and 0.95.

20. The method for forming a semiconductor structure according to claim 11, wherein the gate conductive layer and the gate dielectric layer are combined into a gate, and further comprises forming a plurality of dummy gates located beside the gate, wherein a length of the dummy gate is shorter than a length of the gate.
